(19) United States
(12) Patent Application Publication
(10) Pub. No.: US 2013/0002336 A1
(43) Pub. Date: Jan. 3, 2013

(54) BIDIRECTIONAL SWITCH

(75) Inventor: Satoshi HATSUKAWA, Osaka-shi (JP)

(73) Assignee: SUMITOMO ELECTRIC INDUSTRIES, LTD., Osaka-shi (JP)

(21) Appl. No.: 13/535,068

(22) Filed: Jun. 27, 2012

Related U.S. Application Data
(60) Provisional application No. 61/502,601, filed on Jun. 29, 2011.

(30) Foreign Application Priority Data
Jun. 29, 2011 (JP) 2011-144044

(51) Int. Cl. H03K 17/56

(52) U.S. Cl. 327/419

(57) ABSTRACT

A bidirectional switch according to one embodiment switches bidirectionally the direction of current flowing between a first and a second terminal, and includes: first and second series circuit sections including first and second semiconductor switch elements that do not have a tolerance in a reverse direction, and first and second reverse current blocking diode sections serially connected to the first and second semiconductor switch elements in a forward direction. The first series circuit section and the second series circuit section are connected in parallel between the first and second terminals so that the forward directions of the first and second semiconductor switch elements face opposite to each other. Each of the first and second reverse current blocking diode sections is configured by connecting in parallel a diode containing GaN as a semiconductor material and a diode containing SiC as a semiconductor material.

### CROSS-REFERENCE TO RELATED APPLICATIONS

This application claims priority to Provisional Application Ser. No. 61/502,601 filed on Jun. 29, 2011 and claims the benefit of Japanese Patent Application No. 2011-144044, filed Jun. 29, 2011, all of which are incorporated herein by reference in their entirety.

### BACKGROUND

1. Field

Embodiments of the present invention relate to a bidirectional switch.

2. Description of the Related Art

A bidirectional switch is a switch that can switch the direction of current between both terminals of the bidirectional switch, and includes two semiconductor switch elements. A bidirectional switch has been known as a device essential to a matrix converter expected to be further higher in efficiency than an inverter. In Japanese Patent Laid-Open No. 2010-161887 and Japanese Patent Laid-Open No. 2009-219267, a bidirectional switch adopting a MOSFET using SiC as a semiconductor switch element is disclosed. In Patent document 1, a bidirectional switch is disclosed in which two series circuit sections having an SiC diode serially connected to a MOSFET in the forward direction are connected in parallel so that the directions of currents that flow through each MOSFET face opposite to each other. On the other hand, in Patent document 2, a bidirectional switch is disclosed in which two parallel circuit sections having an SiC diode parallely connected to a MOSFET in the reverse direction are serially connected so that the two parallel circuit sections face opposite to each other.

### SUMMARY

Matrix converters in which a bidirectional switch can be mainly utilized is applied to power sources. Therefore, bidirectional switches are expected to operate at a high voltage. Diodes utilizing SiC can operate at a high voltage, i.e., cause a large current to flow. However, diodes utilizing SiC have a high ON voltage, and increase switching loss.

Therefore, it is an object of the present invention to provide a bidirectional switch that can operate at a high voltage, and in addition, reduce loss at the time of switching.

According to one aspect of the present invention, there is provided a bidirectional switch which bidirectionally switches a direction of current flowing between a first and a second terminal, and includes: a first series circuit section including a first semiconductor switch element that does not have a tolerance in a reverse direction, and a first reverse current blocking diode section serially connected to the first semiconductor switch element in a forward direction; and a second series circuit section including a second semiconductor switch element that does not have a tolerance in a reverse direction, and a second reverse current blocking diode section serially connected to the second semiconductor switch element in a forward direction. The first series circuit section and the second series circuit section are connected in parallel between the first and second terminals so that the forward directions of the first and second semiconductor switch elements face opposite to each other. Each of the first and second reverse current blocking diode sections is configured by parallely connecting a diode containing GaN as a semiconductor material and a diode containing SiC as a semiconductor material.

In the above-described configuration, even if the electrical potential of one of the first and second terminals is higher than that of the other, when the first and second semiconductor switch elements both are in an OFF state, since current does not flow through the first and second semiconductor switch elements, current does not flow between the first and second terminals. In contrast, when the first and second semiconductor switch elements both are in an ON state, if the electrical potential of one of the first and second terminals is higher than that of the other, a forward voltage is applied to one of the first and second series circuit sections, and a reverse voltage is applied to the other. Therefore, current flows between the first and second terminals via one of the first and second series circuit sections to which the forward voltage is applied. Since the first and second series circuit sections are connected in parallel so that the forward directions of the first and second semiconductor switch elements face opposite to each other, the directions of currents flowing through the first and second series circuit sections are opposite to each other. Therefore, the direction of current flowing between the first and second terminals can be switched in accordance with the high/low level of the electrical potential of the first terminal relative to the electrical potential of the second terminal. While the voltages applied to the first and second reverse current blocking diode sections are switched in the forward direction and the reverse direction in accordance with this switching, if the forward voltage does not exceed the ON voltages of the diodes constituting the respective first and second reverse current blocking diode sections, the current does not flow. The ON voltage of a diode containing GaN as its semiconductor material is lower than that of a diode containing SiC as its semiconductor material. Therefore, in the first and second reverse current blocking diode sections in which the two diodes are connected in parallel, when the forward voltage applied to the first or second reverse current blocking diode section is low, current flows through a diode containing GaN as its semiconductor material. If the forward voltage becomes higher, current flows through a diode containing SiC as its semiconductor material. Therefore, since the ON voltages of the first and second reverse current blocking diode sections become lower, switching loss can be reduced. In addition, if the forward voltage becomes higher, current flows through the diode containing the SiC as its semiconductor material. Thus, the bidirectional switch can be used even when a high voltage is applied.

According to another aspect of the present invention, there is provided a bidirectional switch which bidirectionally switches a direction of current flowing between a first and a second terminal, and includes: a first parallel circuit section including a first semiconductor switch element that does not have a tolerance in a reverse direction, and a first reverse current blocking diode section parallely connected to the first semiconductor switch element in a reverse direction; and a second parallel circuit section including a second semiconductor switch element that does not have a tolerance in a reverse direction, and a second reverse current blocking diode section parallely connected to the second semiconductor switch element in a reverse direction, The first parallel circuit section and the second parallel circuit section are serially connected between the first and second terminals so that forward directions of the first and second semiconductor switch elements face opposite to each other. Each of the first and second reverse current blocking diode sections is configured by connecting in parallel a diode containing GaN as a semiconductor material and a diode containing SiC as a semiconductor material.

In this embodiment, the first semiconductor switch element and the second reverse current blocking diode section are connected serially so that their forward directions agree with each other. The second semiconductor switch element and the first reverse current blocking diode section are connected serially so that their forward directions agree with each other. Then, the forward direction of the second semiconductor switch element and the first reverse current blocking diode section is opposite to the forward direction of the first semiconductor switch element and the second reverse current blocking diode section. Therefore, when the first and second semiconductor switch elements both are in an OFF state, even if the electrical potential of one of the first and second terminals is higher than that of the other, since a reverse voltage is applied to one of the first and second reverse current blocking diode sections without fail, current does not flow. In contrast, when the first and second semiconductor switch elements both are in an ON state, if the electrical potential of one of the first and second terminals is higher than that of the other, a forward voltage is applied to the first semiconductor switch element and the second reverse current blocking diode section, and in addition, a reverse voltage is applied to the second semiconductor switch element and the first reverse current blocking diode section; or a reverse voltage is applied to the first semiconductor switch element and the second reverse current blocking diode section, and in addition, a forward voltage is applied to the second semiconductor switch element and the first reverse current blocking diode section. Therefore, current flows between the first and second terminals via the first semiconductor switch element and the second reverse current blocking diode section, or via the second semiconductor switch element and the first reverse current blocking diode section to which a forward voltage is applied in accordance with the high/low level of the electrical potential of the first terminal relative to the electrical potential of the second terminal. At this time, since the forward direction of the second semiconductor switch element and the first reverse current blocking diode section is opposite to the forward direction of the first semiconductor switch element and the second reverse current blocking diode section, the direction of current flowing between the first and second terminals can be switched in accordance with the high/low level of the electrical potential of the first terminal relative to the electrical potential of the second terminal. The voltages applied to the first and second reverse current blocking diode sections are switched in the forward direction and the reverse direction in accordance with this switching. However, if the forward voltage does not exceed the ON voltages of the diodes constituting the respective first and second reverse current blocking diode sections, current does not flow. The ON voltage of a diode containing GaN as its semiconductor material is lower than the ON voltage of a diode containing SiC as its semiconductor material. Therefore, in the first and second reverse current blocking diode sections in which the two diodes are connected in parallel, when the forward voltage applied to the first or second reverse current blocking diode section is low, current flows through a diode containing GaN as its semiconductor material. If the forward voltage becomes higher, current flows through a diode containing SiC as its semiconductor material. Therefore, since the ON voltages of the first and second reverse current blocking diode sections become lower, switching loss can be reduced. In addition, if the forward voltage becomes higher, current can flow through the diode containing the SiC as its semiconductor material. Thus, the bidirectional switch can be used even when a high voltage is applied.

In the above-described bidirectional switches according to one aspect and another aspect, the diode containing GaN as its semiconductor material and the diode containing SiC as its semiconductor material both can be a Schottky barrier diode. Since Schottky barrier diodes have no pn interface, no time necessary for electric charges accumulated in a pn interface to be discharged exists. Therefore, two diodes constituting each of the first and second reverse current blocking diode sections are Schottky barrier diodes, and thereby, a reverse recovery time, i.e., a recovery time is reduced. Thus, switching loss can be further reduced.

As described above, a bidirectional switch that can operate at a high voltage, and in addition, reduce loss at the time of switching is provided.

### BRIEF DESCRIPTION OF THE DRAWINGS

FIG. 1 is a circuit diagram showing a schematic configuration of a bidirectional switch according to a first embodiment.

FIGS. 2(a) and 2(b) are views showing one example of the operation of the bidirectional switch shown in FIG. 1.

FIG. 3 is a graph showing a current characteristic relative to the forward voltage, of a device that blocks a reverse current.

FIG. 4 is a graph showing the frequency dependence of the loss of the bidirectional switch shown in FIG. 1.

FIG. 5 is a circuit diagram showing a schematic configuration of a bidirectional switch according to a second embodiment.

FIGS. 6(a) and 6(b) are views showing one example of the operation of the bidirectional switch shown in FIG. 5.

### DETAILED DESCRIPTION

Embodiments of the present invention will now be described with reference to the drawings. In the description of the drawings, identical components are marked with identical reference numerals, and the duplicate description is omitted. Dimensional ratios in the drawings do not necessarily match those in the descriptions.

### First Embodiment

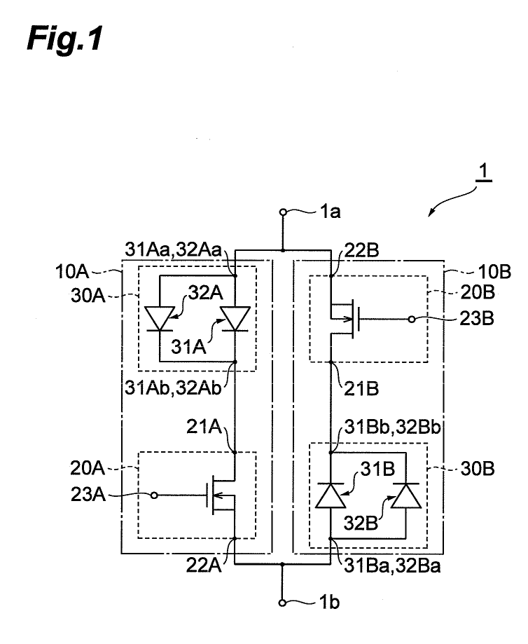

FIG. 1 is a circuit diagram showing a schematic configuration of a bidirectional switch according to an embodiment. A bidirectional switch 1 shown in FIG. 1 is a device which can bidirectionally switch the direction of current flowing between a first terminal 1a and a second terminal 1b. The bidirectional switch 1 can be applied to a matrix converter, or the like. In this case, the first terminal 1a is electrically connected to an AC power source supplying an AC voltage, and the second terminal 1b is connected to a load circuit. An example of the load circuit is a motor. The following describes, as an example, a case where an AC voltage is supplied to the first terminal 1a from an AC power source, and the second terminal 1b is connected to a load circuit.

The bidirectional switch 1 includes: a first series circuit section 10A including a first semiconductor switch element 20A that does not have a tolerance in the reverse direction, and a first reverse current blocking diode section 30A serially connected to the first semiconductor switch element 20A in the forward direction; and a second series circuit section 10B including a second semiconductor switch element 20B that does not have a tolerance in the reverse direction, and a second reverse current blocking diode section 30B serially connected to the second semiconductor switch element 20B in the forward direction.

The first semiconductor switch element 20A includes a first and a second main terminal 21A and 22A, and a control terminal 23A. In the first semiconductor switch element 20A, the direction from the first main terminal 21A toward the second main terminal 22A is the forward direction. Similarly, the second semiconductor switch element 20B includes a first and a second main terminal 21B and 22B, and a control terminal 23B. In the second semiconductor switch element 20B, the direction from the first main terminal 21B toward the second main terminal 22B is the forward direction.

Pulsed signals with reference to the electrical potential of the second main terminals 22A and 22B are input from signal sources for driving the first and second semiconductor switch elements 20A and 20B to the control terminals 23A and 23B, respectively. That is, a pulsed signal is input between the control terminal 23A and the second main terminal 22A, and a pulsed signal is input between the control terminal 23B and the second main terminal 22B. An example of the pulsed signal is a PWM (Pulse Width Modulation) signal.

In the first semiconductor switch element 20A, ON/OFF control of the conductive state between the first and second main terminals 21A and 22A is performed in response to a signal input to the control terminal 23A. When the conductive state between the first and second main terminals 21A and 22A is an ON state, current can flow from the first main terminal 21A to the second main terminal 22A. Similarly, in the second semiconductor switch element 20B, ON/OFF control of the conductive state between the first and second main terminals 21B and 22B is performed in response to a signal input to the control terminal 23B. When the conductive state between the first and second main terminals 21B and 22B is an ON state, current can flow from the first main terminal 21B to the second main terminal 22B.

Respective in-phase pulsed signals are synchronously input to the control terminals 23A and 23B of the first and second semiconductor switch elements 20A and 20B. Therefore, the first and second semiconductor switch elements 20A and 20B can be simultaneously turned on/off. That is, when the first semiconductor switch element 20A is in an ON state, the second semiconductor switch element 20B also is in an ON state, and when the first semiconductor switch element 20A is in an OFF state, the second semiconductor switch element 20B also is in an OFF state.

One example of the first and second semiconductor switch elements 20A and 20B is a MOSFET (Metal-Oxide-Semiconductor Field-Effect Transistor) configured by including a wide band gap semiconductor. One example of the wide band gap semiconductor is SiC or GaN. Therefore, the first and second semiconductor switch elements 20A and 20B each can be a MOSFET containing SiC as its principal component. In the first and second semiconductor switch elements 20A and 20B that are MOSFETs, the first main terminals 21A and 21B are drains, the second main terminals 22A and 22B are sources, and the control terminals 23A and 23B are gates.

The first reverse current blocking diode section 30A is configured by connecting two diodes 31A and 32A in parallel. The diode 31A is a Schottky barrier diode (SBD) containing SiC as its semiconductor material. The diode 32A is an SBD containing GaN as its semiconductor material. An anode terminal 31Aa of the diode 31A and an anode terminal 32Aa of the diode 32A are connected in common. A cathode terminal 31Ab of the diode 31A and a cathode terminal 32Ab of the diode 32A are connected in common. In addition, the cathode terminals 31Ab and 32Ab are connected to the first main terminal 21A of the first semiconductor switch element 20A.

Similarly, the second reverse current blocking diode section 30B is configured by connecting two diodes 31B and 32B in parallel. The diode 31B is an SBD containing SiC as its semiconductor material. The diode 32B is an SBD containing GaN as its semiconductor material. An anode terminal 31Ba of the diode 31B and an anode terminal 32Ba of the diode 32B are connected in common. A cathode terminal 31Bb of the diode 31B and a cathode terminal 32Bb of the diode 32B are connected in common. In addition, the cathode terminals 31Bb and 32Bb are connected to the first main terminal 21B of the second semiconductor switch element 20B.

The first and second series circuit sections 10A and 10B are connected in parallel between the first and second terminals 1a and 1b so that the forward directions of the first and second semiconductor switch elements 20A and 20B face opposite to each other. Specifically, the anode terminals 31Aa and 32Aa of the diodes 31A and 32A that the first reverse current blocking diode section 30A has are connected to the second main terminal 22B of the second semiconductor switch element 20B. The connection point of the anode terminals 31Aa and 32Aa and the second main terminal 22B corresponds to the first terminal 1a. The anode terminals 31Ba and 32Ba of the diodes 31B and 32B that the second reverse current blocking diode section 30B has are connected to the second main terminal 22A of the first semiconductor switch element 20A. The connection point of the anode terminals 31Ba and 32Ba and the second main terminal 22A corresponds to the second terminal 1b.

In the bidirectional switch 1 of the above-described configuration, the high/low level of the electrical potential of the first terminal 1a changes when viewed from the electrical potential of the second terminal 1b, by applying an AC voltage to the first terminal 1a. In this manner, when viewed from the electrical potential of the second terminal 1b, even if the high/low level of the electrical potential of the first terminal 1a changes, when the first and second semiconductor switch elements 20A and 20B both are in an OFF state, current does not flow through the first and second semiconductor switch elements 20A and 20B. Thus, current does not flow between the first and second terminals 1a and 1b. In contrast, when the first and second semiconductor switch elements 20A and 20B both are in an ON state, the direction of current flowing between the first and second terminals 1a and 1b is switched in accordance with the change of the high/low level of the electrical potential of the first terminal 1a when viewed from the second terminal 1b.

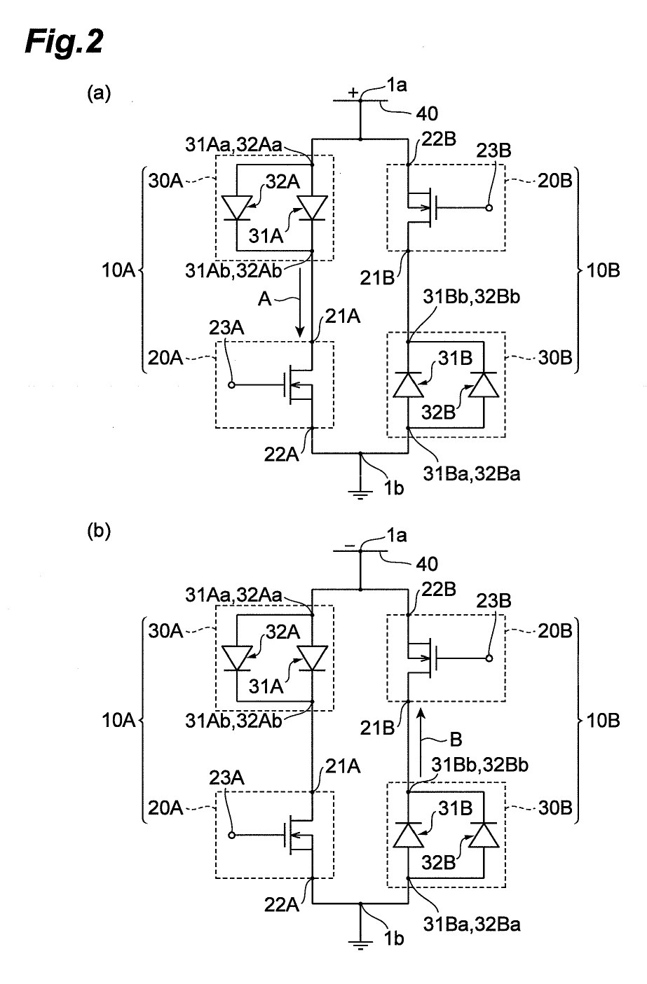

FIGS. 2(a) and 2(b) are views each showing a switching state of the bidirectional switch in accordance with an electrical potential difference between the first terminal and the second terminal. In FIGS. 2(a) and 2(b), a line 40 to which the first terminal 1a is connected indicates a power source line connected to an AC power source. In order to indicate that the second terminal 1b is at a reference electrical potential, the second terminal 1b is grounded for convenience in FIGS. 2(a) and 2(b). “+” in FIG. 2(a) indicates that the first terminal 1a is higher in electrical potential than the second terminal 1b. “−” in FIG. 2(b) indicates that the first terminal 1a is lower in electrical potential than the second terminal 1b.

As shown in FIG. 2(a), when the electrical potential of the first terminal 1a is higher than that of the second terminal 1b, a forward voltage is applied to the first series circuit section 10A, and in contrast, a reverse voltage is applied to the second series circuit section 10B. In this case, in the second semiconductor switch element 20B, although a body diode between the first and second main terminals 21B and 22B turns on, a reverse current does not flow due to the second reverse current blocking diode section 30B. Therefore, current flows from the first terminal 1a toward the second terminal 1b (in the direction of an arrow A in FIG. 2(a)) via the first series circuit section 10A.

Conversely, as shown in FIG. 2(b), when the electrical potential of the second terminal 1b is higher than that of the first terminal 1a, a forward voltage is applied to the second series circuit section 10B, and in contrast, a reverse voltage is applied to the first series circuit section 10A. Therefore, due to a reason similar to that in FIG. 2(a), current flows from the second terminal 1b toward the first terminal 1a (in the direction of an arrow B in FIG. 2(b)) via the second series circuit section 10B.

Therefore, in the bidirectional switch 1, as described above, the direction of current that flows can be bidirectionally switched between the first and second terminals 1a and 1b.

In the bidirectional switch 1 shown in FIG. 1, by including the first and second reverse current blocking diode sections 30A and 30B, switching loss can be reduced. This point will be described. In the following description, the first and second reverse current blocking diode sections 30A and 30B are also referred to as reverse current blocking diode sections 30. The SiC diodes 31A and 31B are also referred to as diodes 31. The GaN diodes 32A and 32B are also referred to as diodes 32. The diodes 31 and 32 are Schottky barrier diodes (SBDs).

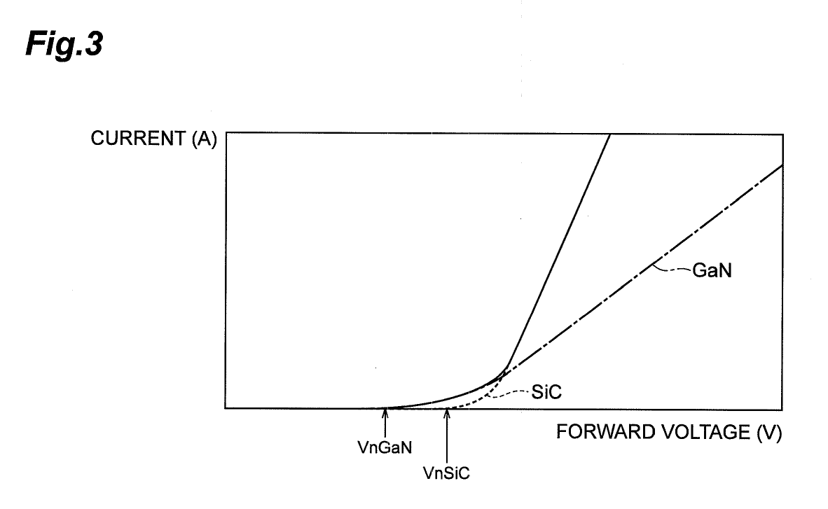

FIG. 3 is a graph showing a relationship between the forward voltage and the current of a Schottky barrier diode containing GaN as its semiconductor material and a Schottky barrier diode containing SiC as its semiconductor material. In FIG. 3, the horizontal axis represents the forward voltage (V), and the longitudinal axis represents the current (A). The chain line and the dashed line in FIG. 3 respectively represent the properties of the SiC SBD and the GaN SBD. The solid line in FIG. 3 represents a property of a circuit in which the SiC SBD and the GaN SBD are connected in parallel. In addition, in FIG. 3, VnSiC indicates the ON voltage of the SiC SBD, and VnGaN indicates the ON voltage of the GaN SBD.

In the SiC SBD and the GaN SBD, all the ON voltages for currents to start flowing in the forward directions are not more than 0.9 V. However, as shown in FIG. 3, the ON voltage of the GaN SBD is lower than that of the SiC SBD. The reverse current blocking diode section 30 is configured by connecting the diode 31 that is an SiC SBD and the diode 32 that is a GaN SBD, in parallel. Therefore, as shown by the solid line in FIG. 3, when the forward voltage is lower than the ON voltage of the SiC SBD, current flows via the diode 32. In contrast, when the forward voltage is higher than the ON voltage of the SiC SBD, a larger current flows via the diode 31. Therefore, the ON voltage of the reverse current blocking diode section 30 in which the diodes 31 and 32 are connected in parallel is lower than that of the case where the reverse current blocking diode section is configured by only the SiC diode 31, for example. In this manner, in the configuration of the reverse current blocking diode section 30, as compared with the case of using the single SiC diode 31 as a device for blocking a reverse current (hereinafter, also referred to as a reverse current blocking device), current flows at a lower ON voltage. As a result, switching loss at the time of switching of the bidirectional switch 1 can be reduced. In addition, it is also possible to increase the switching speed.

Furthermore, since SBDs have no pn interface, no time necessary for electric charges accumulated in a pn interface to be discharged exists. Therefore, the diodes 31 and 32 used in the reverse current blocking diode section 30 are SBDs, and thereby, a reverse recovery time Trr, i.e., a recovery time is reduced. Thus, switching loss can be further reduced.

Meanwhile, since the ON voltage of the GaN diode 32 is lower than that of the SiC diode 31, it can also be considered to configure a reverse current blocking device with the single diode 32. However, GaN SBDs cannot support a large current. Therefore, in the bidirectional switch 1, the reverse current blocking diode section 30 is configured by connecting the diode 32 that is a GaN SBD to the diode 31 that is an SiC SBD, in parallel. Thereby, as shown by the solid line in FIG. 3, when the forward voltage becomes higher, and a large current flows, the larger current can flow via the diode 31. As a result, in the bidirectional switch 1, while realizing reduction in the ON voltage, it is further possible to perform switching at a high voltage exceeding 200 V. Furthermore, as described above, since the ON voltage is low, and switching loss is reduced, switching loss is reduced up to a high frequency domain.

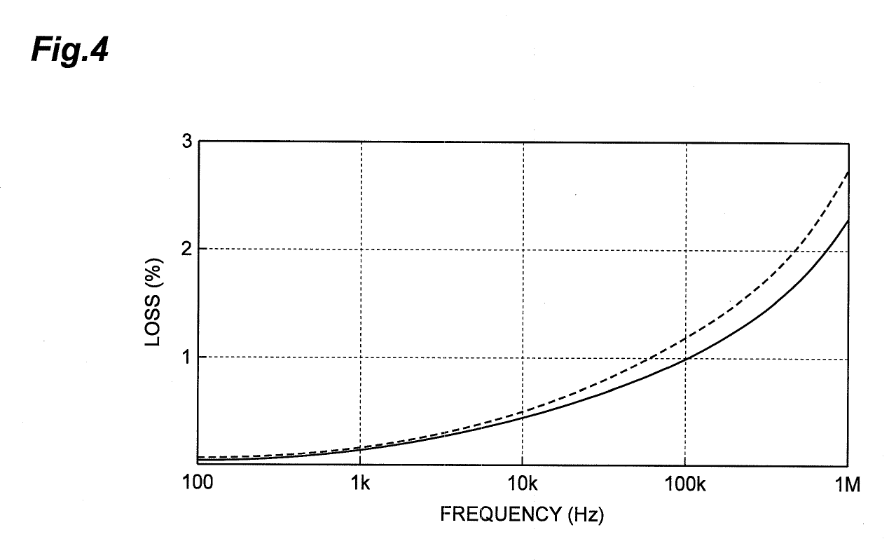

FIG. 4 is an illustrative graph showing loss based on switching, of bidirectional switches. In FIG. 4, the horizontal axis represents the frequency of switching (Hz), and the longitudinal axis represents the loss (%) of the bidirectional switches relative to power at which the bidirectional switches performs switching. The solid line in FIG. 4 indicates the loss of a bidirectional switch in the case of including the reverse current blocking diode section 30 as a reverse current blocking device for blocking a reverse current of the bidirectional switch. The dashed line in FIG. 4 indicates the loss of a bidirectional switch in the case of adopting an SiC SBD in place of the reverse current blocking diode section 30 as a reverse current blocking device of the bidirectional switch. Here, it is assumed that power at which the bidirectional switches perform switching is about 2 KW (200V×10 A). In FIG. 4, the losses shown in the solid line and dashed line have: conduction losses when currents generated for each switching flow through the reverse current blocking devices; and losses transiently generated during the switching of semiconductor switch elements and the reverse current blocking devices included in the bidirectional switches. Therefore, the losses of the bidirectional switches tend to increase together with increase in the switching frequency. Also in this case, when the reverse current blocking diode section 30 is used, since the switching loss is small as compared with the case of using an SiC SBD independently, the loss is reduced as shown by the solid line in FIG. 4.

As described above, in the bidirectional switch 1, while attempting reduction in switching loss by realizing a lower ON voltage, it is possible to perform the switching at a high voltage. Furthermore, by utilizing an SBD, since a recovery time becomes shorter, the switching loss can be further reduced. As described above, by the presence of switching loss, although the loss of the bidirectional switch 1 which increases as the switching frequency becomes higher also tends to increase, since the switching loss is reduced, even if the switching frequency becomes higher, the loss of the entire bidirectional switch 1 also can be reduced.

### Second Embodiment

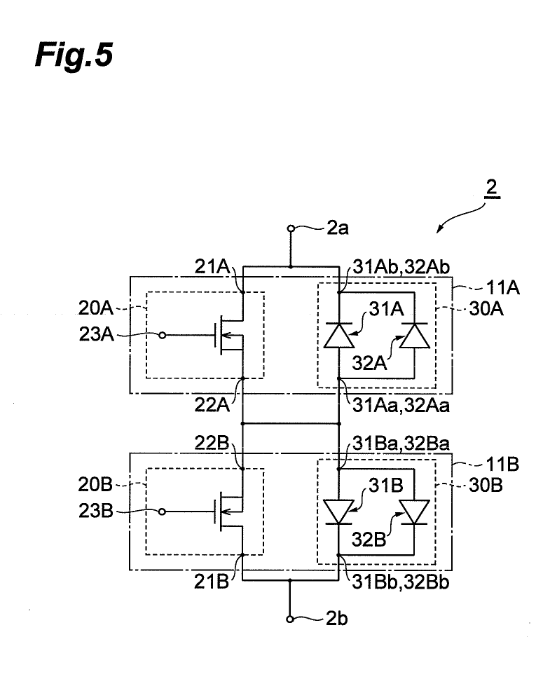

FIG. 5 is a schematic view showing a configuration of a bidirectional switch according to a second embodiment. A bidirectional switch 2 shown in FIG. 5 includes a first parallel circuit section 11A and a second parallel circuit section 11B between a first and a second terminal 2a and 2b. The first and second terminals 2a and 2b correspond to the first and second terminals 1a and 1b of the bidirectional switch 1. That is, the first terminal 2a is connected to an AC power source, and the second terminal 2b is connected to a load circuit.

The first parallel circuit section 11A includes the first semiconductor switch element 20A and the first reverse current blocking diode section 30A connected in parallel in the direction opposite to the first semiconductor switch element 20A. The second parallel circuit section 11B includes the second semiconductor switch element 20B and the second reverse current blocking diode section 30B connected in parallel in the direction opposite to the second semiconductor switch element 20B. Since the configurations of the first and second semiconductor switch elements 20A and 20B, and the configurations of the first and second reverse current blocking diode sections 30A and 30B are the same as those of the first embodiment, description is omitted.

The connection relationship between the first semiconductor switch element 20A and the first reverse current blocking diode section 30A in the first parallel circuit section 11A will be specifically described. The first main terminal 21A of the first semiconductor switch element 20A is connected to the cathode terminals 31Ab and 32Aa of the diodes 31A and 32A that the first reverse current blocking diode section 30A has. The second main terminal 22A of the first semiconductor switch element 20A is electrically connected to the anode terminals 31Aa and 32Aa of the diodes 31A and 32A. The connection point of the first main terminal 21A and the cathode terminals 31Ab and 32Aa corresponds to the first terminal 2a.

Next, the connection relationship between the second semiconductor switch element 20B and the second reverse current blocking diode section 30B in the second parallel circuit section 11B will be specifically described. The second main terminal 22B of the second semiconductor switch element 20B is connected to the anode terminals 31Ba and 32Ba of the diodes 31B and 32B that the second reverse current blocking diode section 30B has. The first main terminal 21B of the second semiconductor switch element 20B is connected to the cathode terminals 31Bb and 32Bb of the diodes 31B and 32B. The connection point of the first main terminal 21B and the cathode terminals 31Bb and 32Bb corresponds to the second terminal 2b.

The first and second parallel circuit sections 11A and 11B are serially connected between the first and second terminals 2a and 2b so that the forward directions of the first and second semiconductor switch elements 20A and 20B face opposite to each other. That is, the connection point of the second main terminal 22A and the anode terminals 31Aa and 32Aa is connected to the connection point of the second main terminal 22B and the anode terminals 31Ba and 32Ba.

Also in the bidirectional switch 2, the high/low level of the electrical potential of the first terminal 2a changes when viewed from the electrical potential of the second terminal 2b, by applying an AC voltage to the first terminal 2a. When the first and second semiconductor switch elements 20A and 20B both are in an OFF state, since the forward directions of the first and second reverse current blocking diode sections 30A and 30B face opposite to each other, current does not flow between the first and second terminals 2a and 2b. In contrast, when the first and second semiconductor switch elements 20A and 20B both are in an ON state, the direction of current flowing between the first and second terminals 2a and 2b is switched in a manner similar to the case of the bidirectional switch 1 in accordance with the change of the high/low level of the electrical potential of the first terminal 2a when viewed from the second terminal 2b.

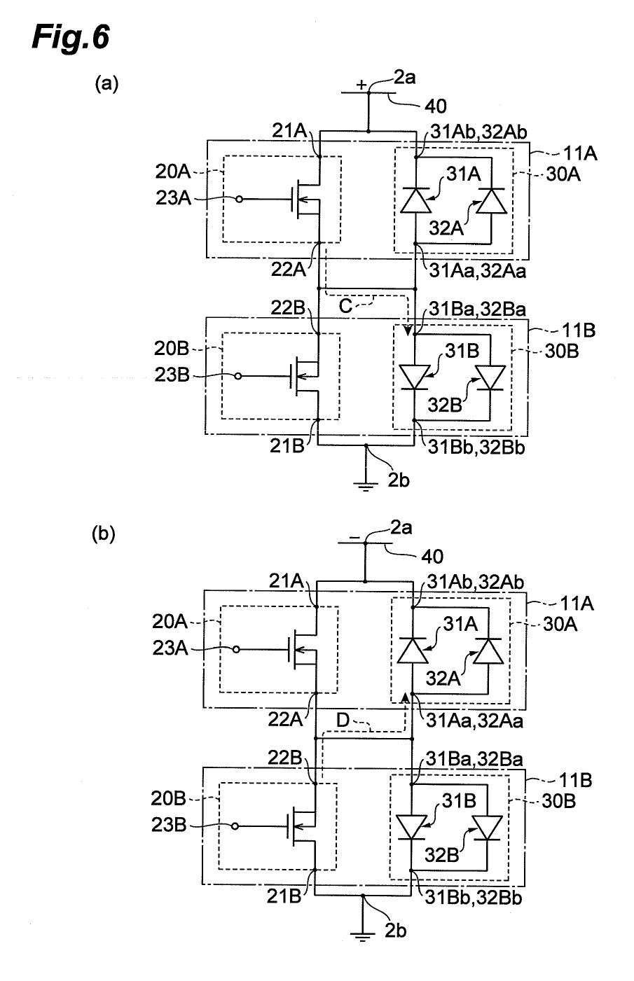

FIGS. 6(a) and 6(b) are views each showing a switching state in accordance with an electrical potential difference between the first terminal and the second terminal. In FIGS. 6(a) and 6(b), the line 40 to which the first terminal 2a is connected indicates a power source line connected to an AC power source in a manner similar to the cases of FIGS. 2(a) and 2(b). The second terminal 2b is grounded for convenience in a manner similar to the cases of FIGS. 2(a) and 2(b). “+” in FIG. 6(a) indicates that the first terminal 2a is higher in electrical potential than the second terminal 2b. “−” in FIG. 6(b) indicates that the first terminal 2a is lower in electrical potential than the second terminal 2b.

As shown in FIG. 6(a), when the electrical potential of the first terminal 2a is higher than that of the second terminal 2b, a forward voltage is applied to the first semiconductor switch element 20A and the second reverse current blocking diode section 30B, and in contrast, a reverse voltage is applied to the second semiconductor switch element 20B and the first reverse current blocking diode section 30A. Therefore, current flows from the first terminal 2a toward the second terminal 2b (in the direction of an arrow C in FIG. 6(a)) via the first semiconductor switch element 20A and the second reverse current blocking diode section 30B.

Conversely, as shown in FIG. 6(b), when the electrical potential of the first terminal 2a is lower than that of the second terminal 2b, a forward voltage is applied to the second semiconductor switch element 20B and the first reverse current blocking diode section 30A, and in contrast, a reverse voltage is applied to the first semiconductor switch element 20A and the second reverse current blocking diode section 30B. Therefore, due to a reason similar to that in FIG. 6(a), current flows from the second terminal 2b toward the first terminal 2a (in the direction of an arrow D in FIG. 6(b)) via the second semiconductor switch element 20B and the first reverse current blocking diode section 30A sides.

As described above, in the bidirectional switch 2, the direction of current that flows can be bidirectionally switched between the first and second terminals 2a and 2b.

Since the bidirectional switch 2 also includes the first and second reverse current blocking diode sections 30A and 30B, the bidirectional switch 2 also has operation and effect similar to those of the bidirectional switch 1 of the first embodiment. That is, each ON voltage of the first and second reverse current blocking diode sections 30A and 30B becomes lower than that in the case of only the SiC diodes 31A and 31B, for example. Therefore, in the bidirectional switch 2, current can flow at an ON voltage lower than that in the case of using the SiC diodes 31A and 31B independently as a reverse current blocking device serving as a device for blocking a reverse current. As a result, switching loss at the time of switching of the bidirectional switch 2 can be reduced. In addition, it is also possible to attempt increasing the switching speed. Furthermore, the diodes 31A, 32A, 31B, and 32B are SBDs, and thereby, a reverse recovery time Trr (recovery time) is reduced. Thus, switching loss can be further reduced. Therefore, in the bidirectional switch 2, switching loss is reduced up to a higher frequency domain. Furthermore, the SIC diode 31A and the GaN diode 32A are connected in parallel, and the SIC diode 31B and the GaN diode 32B are connected in parallel. Thus, it is possible to perform switching at a high voltage exceeding 200V.

Hereinabove, although embodiments of the present invention have been described, the present invention is not limited to the above-described various embodiments, and various modifications can be made in the scope that does not depart from the spirit of the present invention. Diodes constituting the first and second reverse current blocking diode sections are not limited to Schottky barrier diodes, and may be pn junction type diodes. Even if pn junction type diodes are used, diodes utilizing GaN are lower in ON voltage than diodes utilizing SiC. Thus, switching loss can be reduced. However, the kind of two diodes, that is, pn junction type diode and Schottky barrier diode, constituting the first reverse current blocking diode section is the same. This point is also similar to that of the second reverse current blocking diode section.

In addition, the first and second semiconductor switch elements are switch elements utilizing a semiconductor, and do not have a tolerance in the reverse direction. That is, the first and second semiconductor switch elements may be devices for causing current to flow in one direction, and are not limited to MOSFETs. For example, the first and second semiconductor switch elements can be transistors that do not have a tolerance in the reverse direction. Examples of such transistors include an insulated-gate bipolar transistor, a junction type field effect transistor, and a junction type bipolar transistor. When the first and second semiconductor switch elements are insulated-gate bipolar transistors, or junction type bipolar transistors, the control terminals of the semiconductor switch elements are gates, the first main terminals are collectors, and the second main terminals are emitters. When the first and second semiconductor switch elements are junction type field effect transistors, the control terminals of the first and second semiconductor switch elements are gates, the first main terminals are drains, and the second main terminals are sources, in a manner similar to the case of MOS field effect transistors. In addition, the first and second semiconductor switch elements are not limited to a three-terminal type, and may be a four-terminal type.

What is claimed is:

1. A bidirectional switch which bidirectionally switches a direction of current flowing between a first and a second terminal, comprising:
a first series circuit section including a first semiconductor switch element that does not have a tolerance in a reverse direction, and a first reverse current blocking diode section serially connected to the first semiconductor switch element in a forward direction; and
a second series circuit section including a second semiconductor switch element that does not have a tolerance in a reverse direction, and a second reverse current blocking diode section serially connected to the second semiconductor switch element in a forward direction, wherein
the first series circuit section and the second series circuit section are connected in parallel between the first and second terminals so that the forward directions of the first and second semiconductor switch elements face opposite to each other, and wherein
each of the first and second reverse current blocking diode sections is configured by connecting in parallel a diode containing GaN as a semiconductor material and a diode containing SiC as a semiconductor material.

2. A bidirectional switch which bidirectionally switches a direction of current flowing between a first and a second terminal, comprising:
a first parallel circuit section including a first semiconductor switch element that does not have a tolerance in a reverse direction, and a first reverse current blocking diode section parallely connected to the first semiconductor switch element in a reverse direction; and
a second parallel circuit section including a second semiconductor switch element that does not have a tolerance in a reverse direction, and a second reverse current blocking diode section parallely connected to the second semiconductor switch element in a reverse direction, wherein
the first parallel circuit section and the second parallel circuit section are serially connected between the first and second terminals so that forward directions of the first and second semiconductor switch elements face opposite to each other, and wherein
each of the first and second reverse current blocking diode sections is configured by connecting in parallel a diode containing GaN as a semiconductor material and a diode containing SiC as a semiconductor material.

3. The bidirectional switch according to claim 1, wherein the diode containing the GaN as a semiconductor material and the diode containing the SiC as a semiconductor material both are a Schottky barrier diode.

4. The bidirectional switch according to claim 2, wherein the diode containing the GaN as a semiconductor material and the diode containing the SiC as a semiconductor material both are a Schottky barrier diode.
